(19) United States
(12) Patent Application Publication
(10) Pub. No.: US 2025/0385170 A1
(43) Pub. Date: Dec. 18, 2025

(54) CHIP PACKAGE STRUCTURE AND METHOD FOR FORMING THE SAME

(71) Applicant: Taiwan Semiconductor Manufacturing Company, Ltd., Hsinchu (TW)

(72) Inventors: Hung-En HSU, Taipei City (TW); Hsueh-Fu PENG, Taoyuan City (TW); Kuo-Ching HSU, Taipei (TW)

(21) Appl. No.: 18/741,213

(22) Filed: Jun. 12, 2024

(51) Int. Cl. H01L 23/498; H01L 21/311; H01L 23/00

(52) U.S. Cl. CPC H01L 23/49827; H01L 21/31116; H01L 24/16; H01L 24/81; H01L 2224/16235; H01L 2224/81139; H01L 2924/1436

(57) ABSTRACT

A method for forming a chip package structure is provided. The method includes forming a first dielectric layer over a core substrate. The method includes partially removing the first dielectric layer using a first laser process to form a first through hole passing through the first dielectric layer. The method includes forming a first conductive via structure in the first through hole. A first top surface of the first conductive via structure is lower than a second top surface of the first dielectric layer. The method includes bonding a chip structure to the first conductive via structure through a conductive bump. The conductive bump is in direct contact with the first top surface of the first conductive via structure.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements.

Dozens or hundreds of integrated circuits are typically manufactured on a single semiconductor wafer. The individual dies are singulated by sawing the integrated circuits along scribe lines. The individual dies are then packaged separately. The semiconductor industry continues to improve the integration density of various electronic components (e.g., transistors, diodes, resistors, capacitors, etc.) by continual reductions in minimum feature size, which allow more components to be integrated into a given area. However, since feature sizes of dies continue to decrease, feature sizes of an interposer substrate for carrying the dies decrease as well. Therefore, it is a challenge to form reliable packages with the dies and the interposer substrate with small feature sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1I are cross-sectional views of various stages of a process for forming a chip package structure, in accordance with some embodiments.

FIG. 1F-1 is a perspective view of the chip package structure of FIG. 1F, in accordance with some embodiments.

FIG. 1G-1 is a perspective view of the chip package structure of FIG. 1G, in accordance with some embodiments.

FIG. 1G-2 is a cross-sectional view illustrating the chip package structure along a sectional line II-II′ in FIG. 1G-1, in accordance with some embodiments.

FIGS. 2A-2F are cross-sectional views of various stages of a process for forming a chip package structure, in accordance with some embodiments.

FIGS. 3A-3C are cross-sectional views of various stages of a process for forming a chip package structure, in accordance with some embodiments.

FIG. 3B-1 is a perspective view of the chip package structure of FIG. 3B, in accordance with some embodiments.

FIGS. 4A-4C are cross-sectional views of various stages of a process for forming a chip package structure, in accordance with some embodiments.

FIG. 4B-1 is a perspective view of the chip package structure of FIG. 4B, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

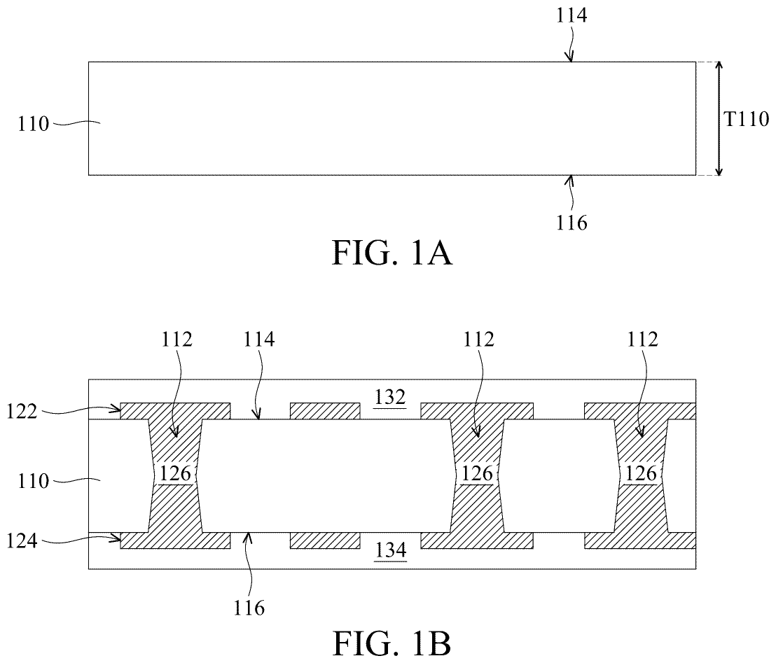

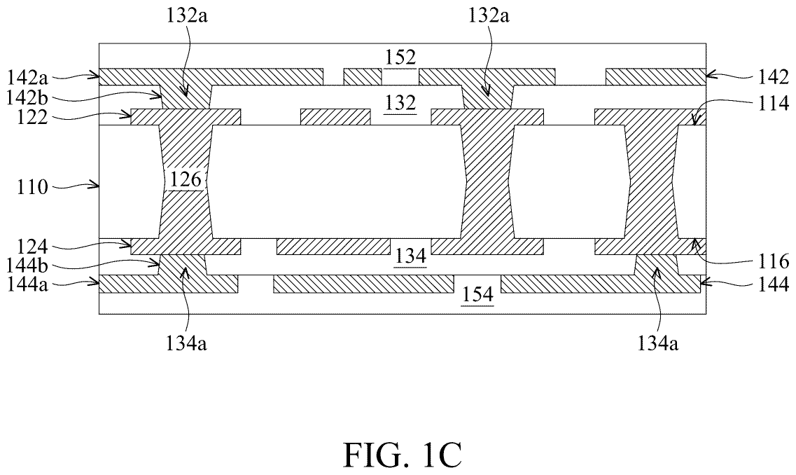

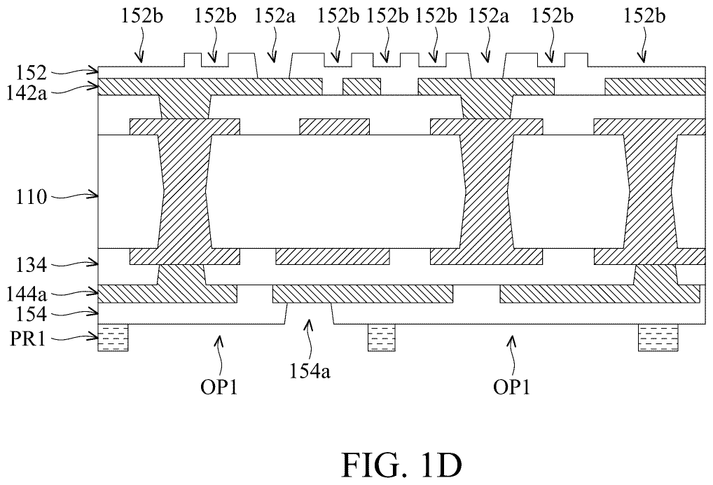

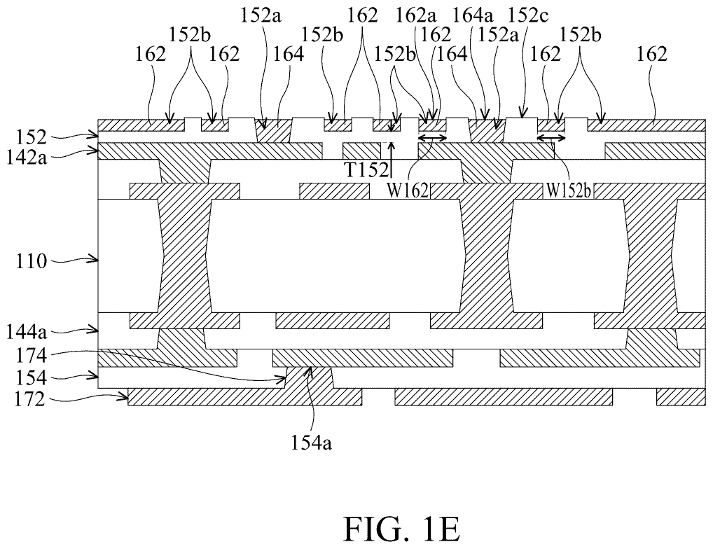

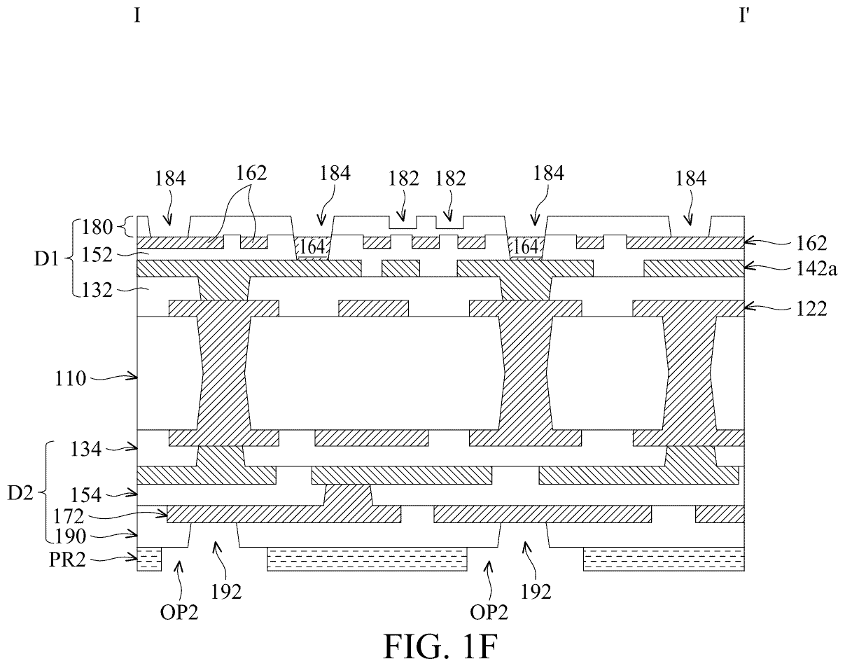

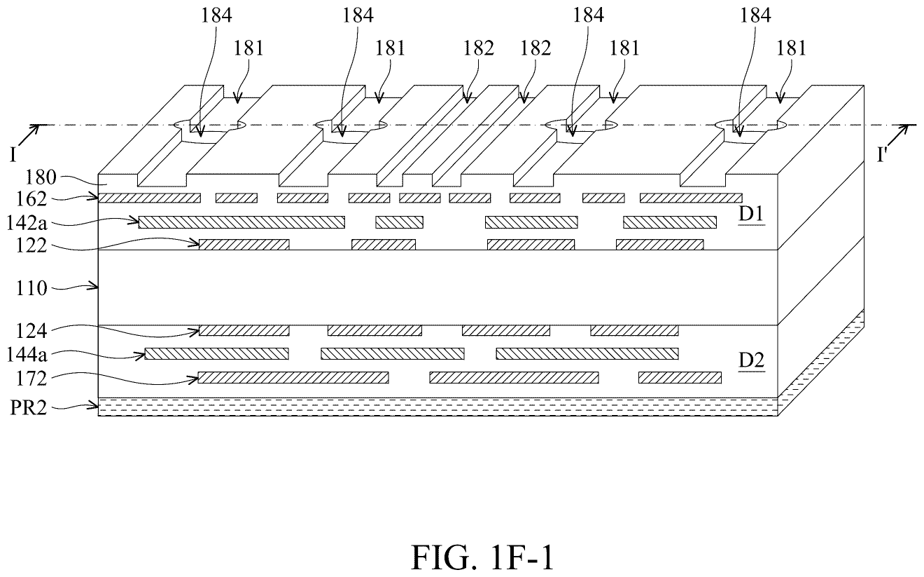

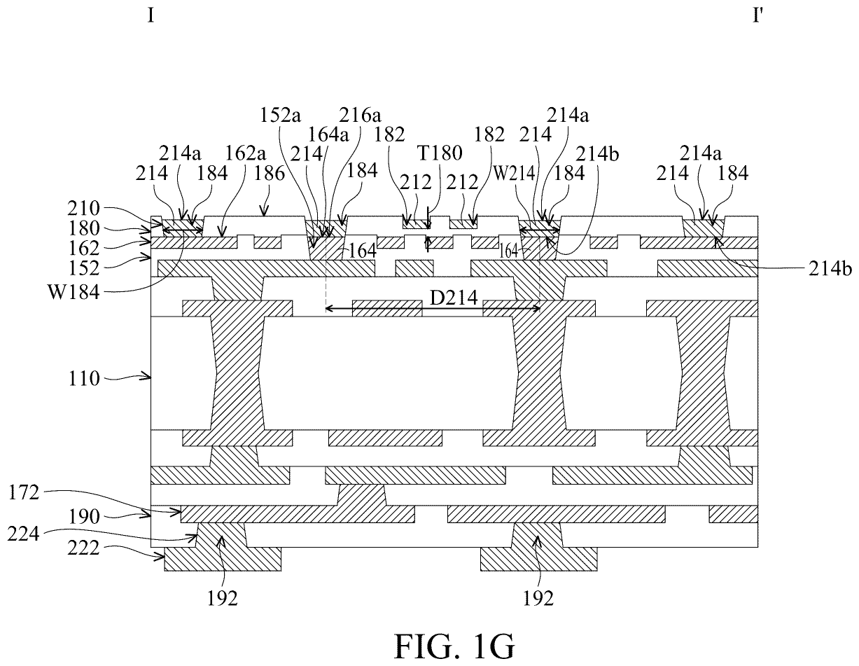

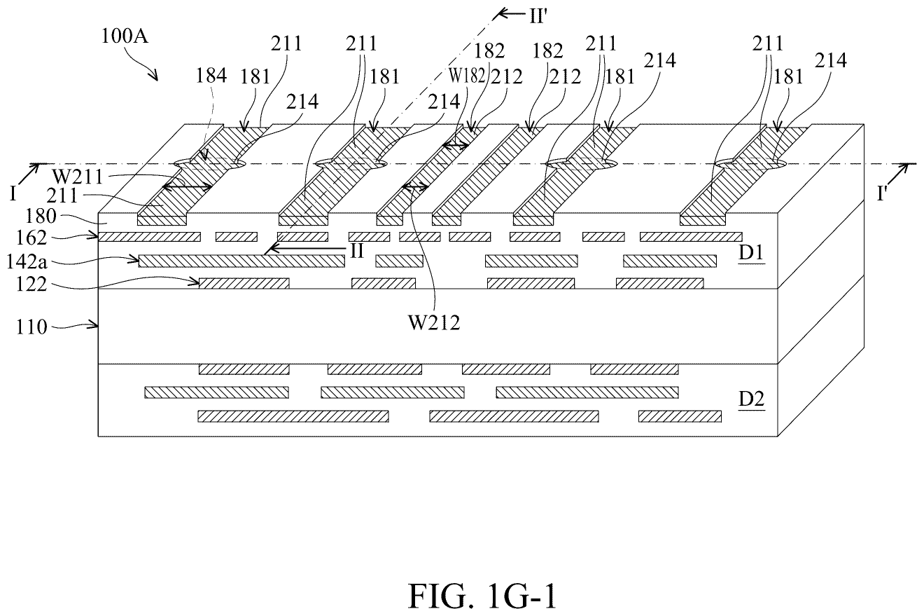

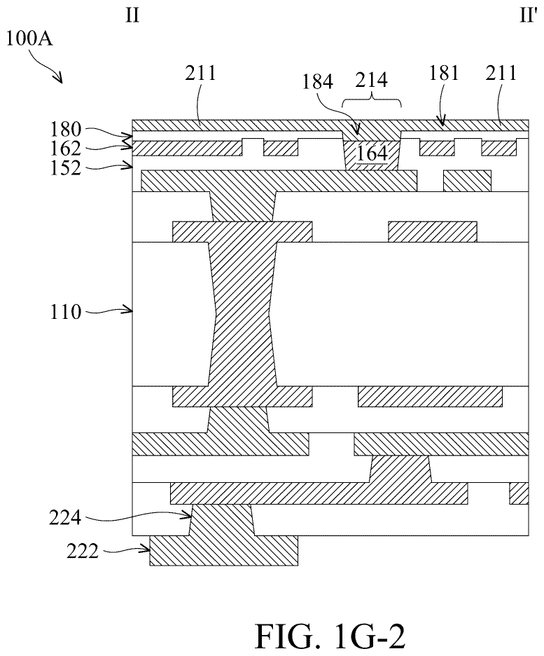

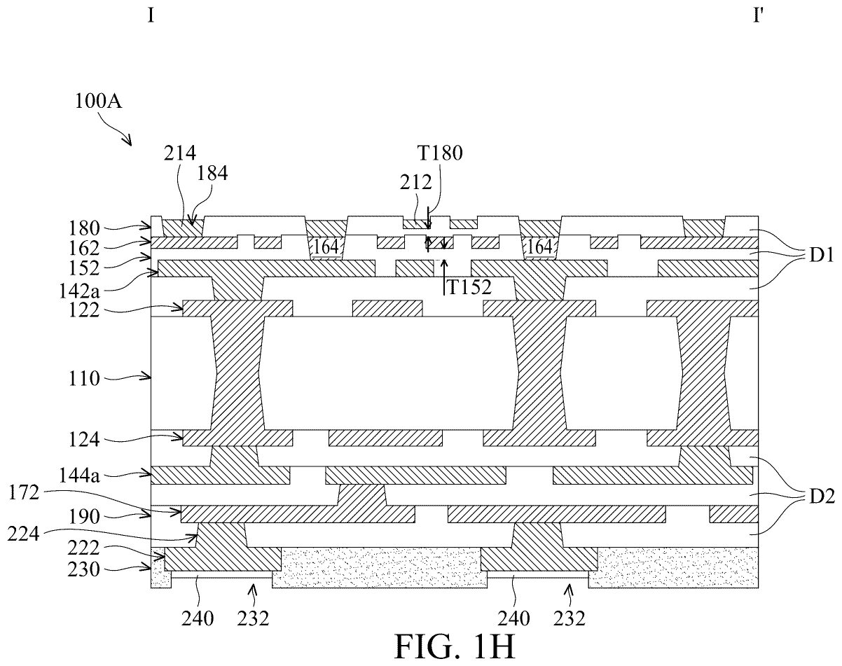

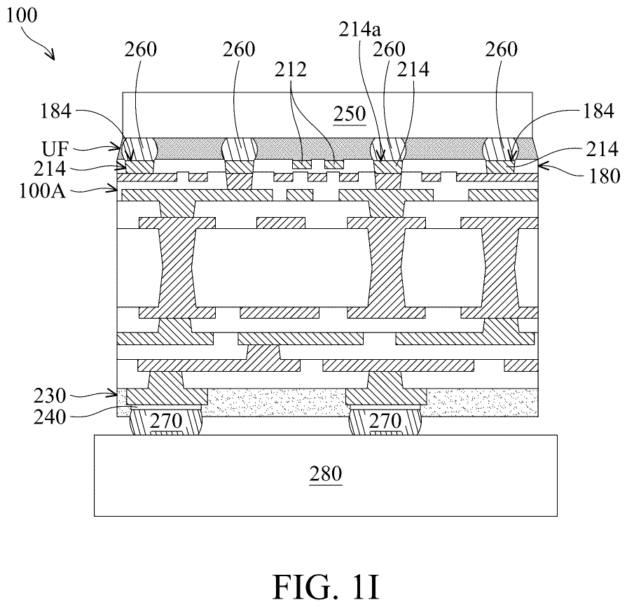

FIGS. 1A-1I are cross-sectional views of various stages of a process for forming a chip package structure, in accordance with some embodiments. As shown in FIG. 1A, a core substrate 110 is provided, in accordance with some embodiments. The core substrate 110 has surfaces 114 and 116, in accordance with some embodiments. The surfaces 114 and 116 are opposite to each other, in accordance with some embodiments. The thickness T110 of the core substrate 110 ranges from about 150 μm to about 250 μm, in accordance with some embodiments.

In some embodiments, the core substrate 110 is made of organic materials such as epoxy, resin, glass fiber, molding compound, plastic (such as polyvinylchloride (PVC), acrylonitril, butadiene and styrene (ABS), polypropylene (PP), polyethylene (PE), polystyrene (PS), polymethyl methacrylate (PMMA), polyethylene terephthalate (PET), polycarbonates (PC), polyphenylene sulfide (PPS)), the like, or a combination thereof. In some other embodiments, the core substrate 110 is made of a conductive material (e.g., metal or alloy), a semiconductor material (e.g., silicon), glass, the like, a combination thereof, or another suitable material.

As shown in FIG. 1B, portions of the core substrate 110 are removed to form through holes 112 in the core substrate 110, in accordance with some embodiments. The through holes 112 pass through the core substrate 110, in accordance with some embodiments. The through holes 112 are formed using a drilling process, such as a laser drilling process, an etching process, or another suitable process.

As shown in FIG. 1B, wiring layers 122 and 124 and conductive via structures 126 are formed, in accordance with some embodiments. The wiring layer 122 is formed over the surface 114, in accordance with some embodiments. The wiring layer 124 is formed over the surface 116, in accordance with some embodiments. The conductive via structures 126 are formed in the through holes 112, in accordance with some embodiments.

The wiring layers 122 and 124 and conductive via structures 126 are made of a conductive material, such as metal (e.g. copper, aluminum, or tungsten) or alloys thereof, in accordance with some embodiments.

The formation of the wiring layers 122 and 124 and conductive via structures 126 includes forming a seed layer (not shown) over the surfaces 114 and 116 and in the through holes 112; forming a photoresist layer (not shown) over the seed layer, wherein the photoresist layer has openings exposing portions of the seed layer; performing an electroplating plating process to form a conductive layer in the openings; and removing the photoresist layer and the seed layer thereunder, in accordance with some embodiments. The conductive layer and the seed layer thereunder together form the wiring layers 122 and 124 and the conductive via structures 126, in accordance with some embodiments.

As shown in FIG. 1B, dielectric layers 132 and 134 are formed over the surfaces 114 and 116 respectively, in accordance with some embodiments. The dielectric layer 132 covers the wiring layer 122, in accordance with some embodiments. The dielectric layer 134 covers the wiring layer 124, in accordance with some embodiments.

The dielectric layers 132 and 134 include an Ajinomoto Build-up Film (ABF) or a prepreg sheet, in accordance with some embodiments. The dielectric layers 132 and 134 are made of an insulating material such as a polymer material (e.g., polybenzoxazole, polyimide, or a photosensitive material), nitride (e.g., silicon nitride), oxide (e.g., silicon oxide), silicon oxynitride, or the like, in accordance with some embodiments. In some embodiments, the dielectric layers 132 and 134 are made of the same material. In some other embodiments, the dielectric layers 132 and 134 are made of different materials.

As shown in FIG. 1C, wiring structures 142 and 144 are formed over opposite surfaces 114 and 116 of the core substrate 110, in accordance with some embodiments. The wiring structure 142 includes a wiring layer 142a and conductive vias 142b, in accordance with some embodiments.

The wiring layer 142a is formed over the dielectric layer 132, in accordance with some embodiments. The conductive vias 142b are formed in the dielectric layer 132, in accordance with some embodiments. The conductive vias 142b are connected between the wiring layers 142a and 122, in accordance with some embodiments.

The wiring structure 144 includes a wiring layer 144a and conductive vias 144b, in accordance with some embodiments. The wiring layer 144a is formed under the dielectric layer 134, in accordance with some embodiments. The conductive vias 144b are formed in the dielectric layer 134, in accordance with some embodiments. The conductive vias 144b are connected between the wiring layers 144a and 124, in accordance with some embodiments.

The wiring structure 142 is made of a conductive material, such as metal (e.g. copper, aluminum, or tungsten) or alloys thereof, in accordance with some embodiments. The wiring structure 144 is made of a conductive material, such as metal (e.g. copper, aluminum, or tungsten) or alloys thereof, in accordance with some embodiments.

The formation of the wiring structures 142 and 144 includes partially removing the dielectric layers 132 and 134 to form through holes 132a and 134a in the dielectric layers 132 and 134 respectively; forming a first seed layer (not shown) and a second seed layer (not shown) over the dielectric layers 132 and 134 and in the through holes 132a and 134a respectively; forming a first photoresist layer (not shown) and a second photoresist layer (not shown) over the first seed layer and the second seed layer respectively, wherein the first photoresist layer has first openings exposing portions of the first seed layer, and the second photoresist layer has second openings exposing portions of the second seed layer; performing an electroplating plating process to form a first conductive layer in the first openings and a second conductive layer in the second openings; and removing the first photoresist layer, the first seed layer thereunder, the second photoresist layer, and the second seed layer thereunder, in accordance with some embodiments.

The first conductive layer and the first seed layer thereunder together form the wiring structure 142, in accordance with some embodiments. The second conductive layer and the second seed layer thereunder together form the wiring structure 144, in accordance with some embodiments.

As shown in FIG. 1C, a dielectric layer 152 is formed over the dielectric layer 132 and the wiring structure 142, in accordance with some embodiments. As shown in FIG. 1C, a dielectric layer 154 is formed over the dielectric layer 134 and the wiring structure 144, in accordance with some embodiments.

The dielectric layer 152 includes an Ajinomoto Build-up Film (ABF) or a prepreg sheet, in accordance with some embodiments. The dielectric layer 152 is made of an insulating material such as a polymer material (e.g., polybenzoxazole, polyimide, or a photosensitive material), nitride (e.g., silicon nitride), oxide (e.g., silicon oxide), silicon oxynitride, or the like, in accordance with some embodiments.

The dielectric layer 154 includes an Ajinomoto Build-up Film (ABF) or a prepreg sheet, in accordance with some embodiments. The dielectric layer 154 is made of an insulating material such as a polymer material (e.g., polybenzoxazole, polyimide, or a photosensitive material), nitride (e.g., silicon nitride), oxide (e.g., silicon oxide), silicon oxynitride, or the like, in accordance with some embodiments.

In some embodiments, the dielectric layers 152 and 154 are made of the same material. In some other embodiments, the dielectric layers 152 and 154 are made of different materials.

As shown in FIG. 1D, portions of the dielectric layer 152 are removed to form through holes 152a and trenches 152b in the dielectric layer 152, in accordance with some embodiments. The through holes 152a pass through the dielectric layer 152 and expose portions of the wiring layer 142a, in accordance with some embodiments.

The trenches 152b do not pass through the dielectric layer 152, in accordance with some embodiments. The removal process includes a laser process such as an excimer laser process, in accordance with some embodiments.

As shown in FIG. 1D, portions of the dielectric layer 154 are removed to form through holes 154a, in accordance with some embodiments. The through holes 154a pass through the dielectric layer 154 and expose portions of the wiring layer 144a, in accordance with some embodiments. The removal process includes a laser process, in accordance with some embodiments.

As shown in FIG. 1D, a photoresist layer PR1 is formed under the dielectric layer 154, in accordance with some embodiments. The photoresist layer PR1 has openings OP1, in accordance with some embodiments. The opening OP1 is connected to the through hole 154a, in accordance with some embodiments. The photoresist layer PR1 is made of a photoresist material such as a polymer material, in accordance with some embodiments.

As shown in FIG. 1E, conductive lines 162 and conductive via structures 164 are formed in the trenches 152b and the through holes 152a respectively, in accordance with some embodiments. The conductive via structures 164 are connected to the wiring layer 142a thereunder, in accordance with some embodiments.

The line width W162 of the conductive line 162 is less than the average width of the conductive via structure 164, in accordance with some embodiments. Since the trenches 152b are formed by an excimer laser process, the width W152b of the trench 152b can be reduced, in accordance with some embodiments. Therefore, the line width W162 of the conductive line 162 can be reduced, in accordance with some embodiments. The line width W162 ranges from about 5 μm to about 10 μm, in accordance with some embodiments.

As a result, the density of the conductive lines 162 is improved, which improves the signal transmission efficiency, in accordance with some embodiments. Furthermore, since the line width W162 of the conductive line 162 is reduced, the thickness T152 of the dielectric layer 152 is reduced, in accordance with some embodiments. The thickness T152 of the dielectric layer 152 ranges from about 5 μm to about 10 μm, in accordance with some embodiments.

The top surface 164a of the conductive via structure 164 is lower than the top surface 152c of the dielectric layer 152, in accordance with some embodiments. The top surface 162a of the conductive line 162 is lower than the top surface 152c of the dielectric layer 152, in accordance with some embodiments.

The conductive lines 162 and the conductive via structures 164 are made of a conductive material, such as metal (e.g. copper, aluminum, or tungsten) or alloys thereof, in accordance with some embodiments. The conductive lines 162 and the conductive via structures 164 are formed using an electroplating process and an etching process, in accordance with some embodiments.

As shown in FIGS. 1D and 1E, a wiring layer 172 and conductive via structures 174 are formed in the openings OP1 of the photoresist layer PR1 and the through holes 154a of the dielectric layer 154 respectively, in accordance with some embodiments. The conductive via structures 174 are connected to the wiring layer 144a thereover, in accordance with some embodiments.

The wiring layer 172 and the conductive via structures 174 are made of a conductive material, such as metal (e.g. copper, aluminum, or tungsten) or alloys thereof, in accordance with some embodiments. As shown in FIG. 1E, the photoresist layer PR1 is removed, in accordance with some embodiments.

FIG. 1F-1 is a perspective view of the chip package structure of FIG. 1F, in accordance with some embodiments. FIG. 1F is a cross-sectional view illustrating the chip package structure along a sectional line I-I′ in FIG. 1F-1, in accordance with some embodiments.

As shown in FIGS. 1F and 1F-1, a dielectric layer 180 is formed over the dielectric layer 152, the conductive lines 162, and the conductive via structure 164, in accordance with some embodiments. The dielectric layers 132, 152 and 180 together form a dielectric structure D1, in accordance with some embodiments. The dielectric layer 180 includes an Ajinomoto Build-up Film (ABF) or a prepreg sheet, in accordance with some embodiments.

The dielectric layer 180 is made of an insulating material such as a polymer material (e.g., polybenzoxazole, polyimide, or a photosensitive material), nitride (e.g., silicon nitride), oxide (e.g., silicon oxide), silicon oxynitride, or the like, in accordance with some embodiments.

As shown in FIGS. 1F and 1F-1, a dielectric layer 190 is formed over the dielectric layer 154 and the wiring layer 172, in accordance with some embodiments. The dielectric layers 134, 154 and 190 together form a dielectric structure D2, in accordance with some embodiments. The dielectric layer 190 includes an Ajinomoto Build-up Film (ABF) or a prepreg sheet, in accordance with some embodiments.

The dielectric layer 190 is made of an insulating material such as a polymer material (e.g., polybenzoxazole, polyimide, or a photosensitive material), nitride (e.g., silicon nitride), oxide (e.g., silicon oxide), silicon oxynitride, or the like, in accordance with some embodiments.

As shown in FIGS. 1F and 1F-1, the dielectric layer 180 is partially removed to form trenches 181 and 182 and through holes 184 in the dielectric layer 180, in accordance with some embodiments. The through holes 184 pass through the dielectric layer 180, in accordance with some embodiments. The through holes 184 expose the conductive lines 162 and the conductive via structures 164, in accordance with some embodiments.

The trenches 181 and 182 do not pass through the dielectric layer 180, in accordance with some embodiments. The trench 181 is connected to the corresponding through hole 184, in accordance with some embodiments. The trench 181 is spaced apart from the trench 182, in accordance with some embodiments.

The trench 181 is wider than the trench 182, in accordance with some embodiments. The trenches 181 and 182 are shallower than the through hole 184, in accordance with some embodiments.

The removal process includes a laser process such as an excimer laser process, in accordance with some embodiments. In some embodiments, the trenches 181 and 182 are formed using a first excimer laser process, and the through holes 184 are formed using a second excimer laser process. In some other embodiments, the trenches 181 and 182 and the through holes 184 are formed using an excimer laser process.

As shown in FIG. 1F, the dielectric layer 190 is partially removed to form through holes 192 in the dielectric layer 190, in accordance with some embodiments. The through holes 192 pass through the dielectric layer 190, in accordance with some embodiments. The through holes 192 expose the wiring layer 172, in accordance with some embodiments. The removal process includes a laser process, in accordance with some embodiments.

As shown in FIGS. 1F and 1F-1, a photoresist layer PR2 is formed under the dielectric layer 190, in accordance with some embodiments. The photoresist layer PR2 has openings OP2, in accordance with some embodiments. The opening OP2 is connected to the corresponding through hole 192, in accordance with some embodiments. The photoresist layer PR2 is made of a photoresist material such as a polymer material, in accordance with some embodiments.

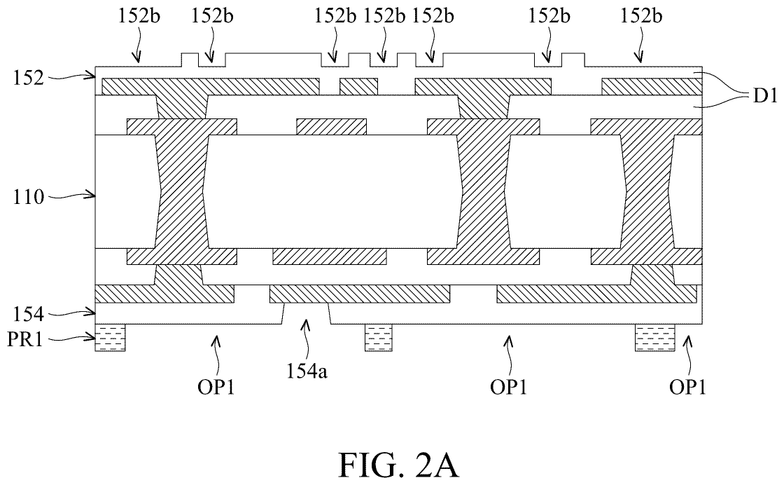

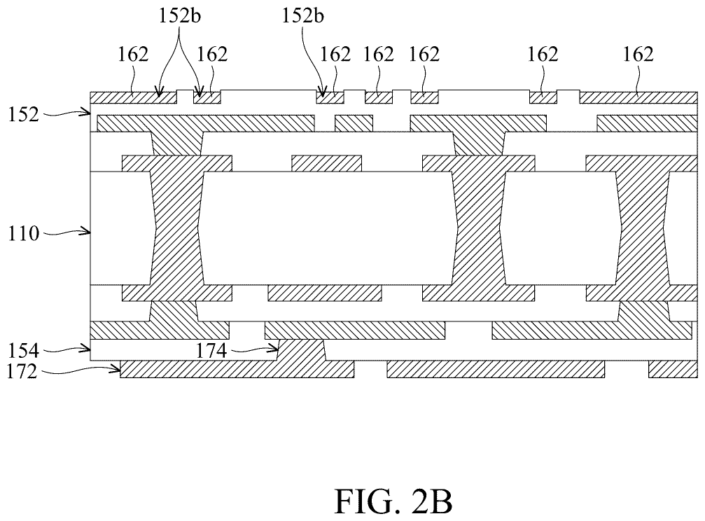

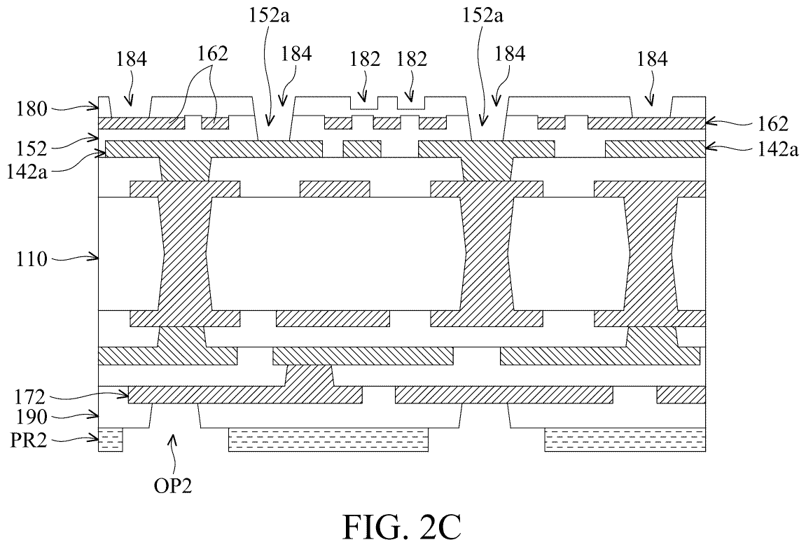

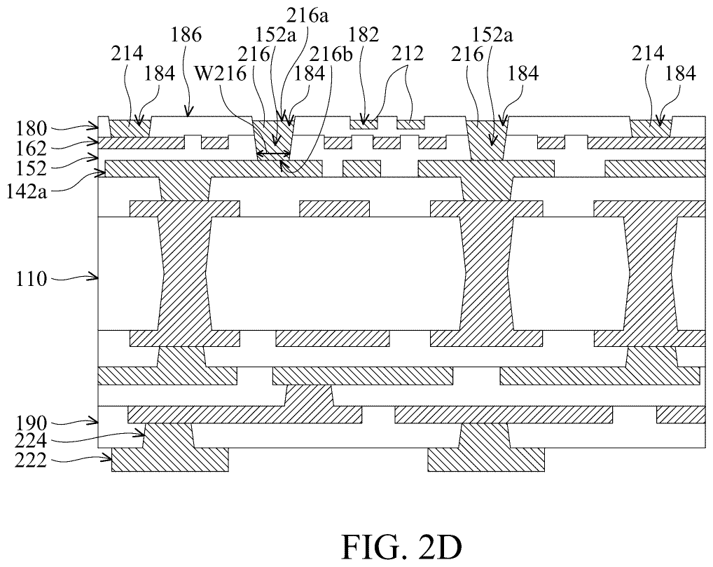

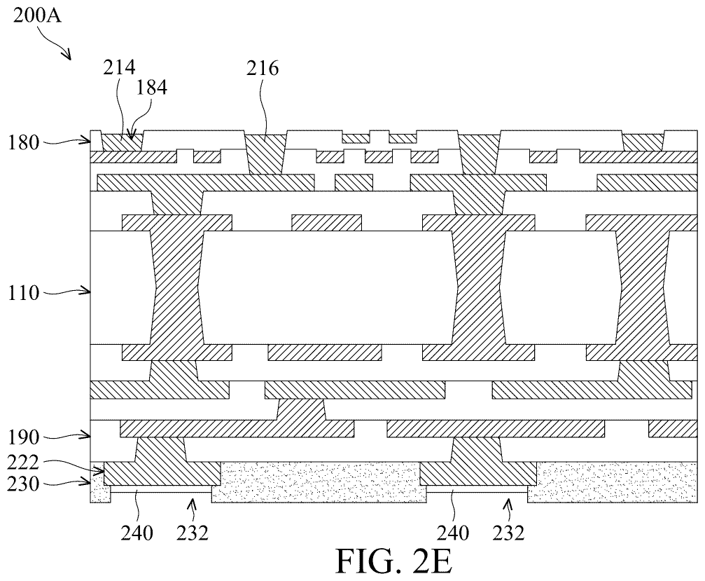

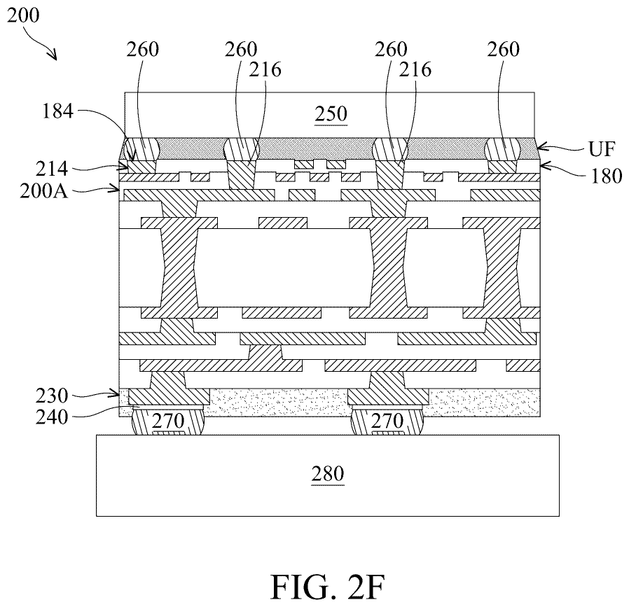

FIG. 1G-1 is a perspective view of the chip package structure of FIG. 1G, in accordance with some embodiments. FIG. 1G is a cross-sectional view illustrating the chip package structure along a sectional line I-I′ in FIG. 1G-1, in accordance with some embodiments. FIG. 1G-2 is a cross-sectional view illustrating the chip package structure along a sectional line II-II′ in FIG. 1G-1, in accordance with some embodiments.

As shown in FIGS. 1G, 1G-1, and 1G-2, conductive lines 211 and 212 and conductive via structures 214 are formed in the trenches 181 and 182 and the through holes 184 respectively, in accordance with some embodiments. The conductive lines 211 are connected to the conductive via structures 214, in accordance with some embodiments.

The top surface 214a of the conductive via structure 214 is lower than the top surface 186 of the dielectric layer 180, in accordance with some embodiments. The conductive via structure 214 is on the top surface 164a of the corresponding conductive via structure 164, in accordance with some embodiments. The conductive via structure 214 is in direct contact with the top surface 164a of the corresponding conductive via structure 164, in accordance with some embodiments.

The conductive via structure 214 is on the top surface 162a of the corresponding conductive line 162, in accordance with some embodiments. The conductive via structure 214 is in direct contact with the top surface 162a of the corresponding conductive line 162, in accordance with some embodiments. The conductive via structure 214 is partially in the through hole 152a, in accordance with some embodiments.

The width W214 of the conductive via structure 214 continuously increases from a bottom surface 214b of the conductive via structure 214 to the top surface 214a of the conductive via structure 214, in accordance with some embodiments. The conductive via structure 214 has a trapezoid shape, in accordance with some embodiments.

As shown in FIG. 1G-1, the line width W211 of the conductive line 211 is less than the average width of the conductive via structure 214, in accordance with some embodiments. The line width W212 of the conductive line 212 is less than the line width W211 of the conductive line 211, in accordance with some embodiments. The line width W212 of the conductive line 212 is less than the average width of the conductive via structure 214, in accordance with some embodiments.

As shown in FIGS. 1G, 1G-1, and 1G-2, since the trenches 182 are formed by an excimer laser process, the width W182 of the trench 182 can be reduced, in accordance with some embodiments. Therefore, the line width W212 of the conductive line 212 can be reduced, in accordance with some embodiments. The line width W212 ranges from about 5 μm to about 10 μm, in accordance with some embodiments.

As a result, the density of the conductive lines 212 is improved, which improves the signal transmission efficiency, in accordance with some embodiments. Furthermore, since the line width W212 of the conductive line 212 is reduced, the thickness T180 of the dielectric layer 180 is reduced, in accordance with some embodiments. The thickness T180 of the dielectric layer 180 ranges from about 5 μm to about 10 μm, in accordance with some embodiments.

As shown in FIG. 1G, similarly, since the through holes 184 are formed by an excimer laser process, the width W184 of the through hole 184 can be reduced, in accordance with some embodiments. Therefore, the width W214 of the conductive via structure 214 can be reduced, in accordance with some embodiments. The width W214 of the conductive via structure 214 ranges from about 10 μm to about 20 μm, in accordance with some embodiments.

Since the width W214 of the conductive via structure 214 is reduced, the distance D214 between two adjacent conductive via structures 214 is reduced, in accordance with some embodiments. The distance D214 is also referred to as a pitch, in accordance with some embodiments. The distance D214 ranges from about 25 μm to about 60 μm, in accordance with some embodiments.

The conductive lines 211 and 212 and conductive via structures 214 are made of a conductive material, such as metal (e.g. copper, aluminum, or tungsten) or alloys thereof, in accordance with some embodiments. The conductive lines 211 and 212 and conductive via structures 214 are formed using an electroplating process and an etching process, in accordance with some embodiments.

As shown in FIGS. 1F and 1G, bonding pads 222 and conductive via structures 224 are formed in the openings OP2 of the photoresist layer PR2 and the through holes 192 of the dielectric layer 190 respectively, in accordance with some embodiments. The conductive via structures 224 are connected to the wiring layer 172 thereover, in accordance with some embodiments.

The bonding pads 222 and the conductive via structures 224 are made of a conductive material, such as metal (e.g. copper, aluminum, or tungsten) or alloys thereof, in accordance with some embodiments. As shown in FIG. 1G, the photoresist layer PR2 is removed, in accordance with some embodiments.

As shown in FIG. 1H, a solder resist layer 230 is formed over the dielectric layer 190 and the bonding pads 222, in accordance with some embodiments. The solder resist layer 230 has openings 232, in accordance with some embodiments. The openings 232 expose the bonding pads 222 thereover, in accordance with some embodiments. The solder resist layer 230 is made of an insulating material such as a polymer material, in accordance with some embodiments.

As shown in FIG. 1H, a surface treatment layer 240 is formed under the bonding pads 222, in accordance with some embodiments. The surface treatment layer 240 is made of a material selected from the group consisting of electroplated nickel/gold, electroless nickel/gold, electroless nickel immersion gold (ENIG), electroless nickel electroless palladium immersion gold (ENEPIG), immersion tin and organic solderability preservative (OSP), in accordance with some embodiments.

In this step, a substrate 100A is substantially formed, in accordance with some embodiments. Since the thickness T180 of the dielectric layer 180 and the thickness T152 of the dielectric layer 152 are reduced, the thickness of the substrate 100A is reduced, in accordance with some embodiments.

As shown in FIG. 1I, a chip structure 250 is bonded to the conductive via structures 214 through conductive bumps 260, in accordance with some embodiments. In some embodiments, the chip structure 250 includes a chip. The chip includes a substrate, in accordance with some embodiments. In some embodiments, the substrate is made of an elementary semiconductor material including silicon or germanium in a single crystal structure, a polycrystal structure, or an amorphous structure.

In some other embodiments, the substrate is made of a compound semiconductor, such as silicon carbide, gallium arsenide, gallium phosphide, indium phosphide, indium arsenide, an alloy semiconductor, such as SiGe, or GaAsP, or a combination thereof. The substrate may also include multi-layer semiconductors, semiconductor on insulator (SOI) (such as silicon on insulator or germanium on insulator), or a combination thereof.

In some embodiments, the substrate includes various device elements. In some embodiments, the various device elements are formed in and/or over the substrate. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to define active regions and electrically isolate various device elements formed in and/or over the substrate in the active regions. In some embodiments, the isolation features include shallow trench isolation (STI) features, local oxidation of silicon (LOCOS) features, other suitable isolation features, or a combination thereof.

In some other embodiments, the chip structure 250 includes a chip package, such as a dynamic random access memory (DRAM) package or a high bandwidth memory (HBM) package. The chip package includes a chip scale package, such as a wafer level chip scale package. In some embodiments, the chip package includes one chip. In some other embodiments, the chip package includes multiple chips, which are arranged side by side or stacked with each other (e.g., a 3D packaging or a 3DIC device).

The conductive bumps 260 are in direct contact with the top surfaces 214a of the conductive via structures 214, in accordance with some embodiments. The conductive bump 260 extends into the dielectric layer 180, in accordance with some embodiments.

The conductive bump 260 is partially in the through hole 184 of the dielectric layer 180, in accordance with some embodiments. The conductive bumps 260 are made of a conductive material such as tin (Sn) or alloys thereof, in accordance with some embodiments.

Since the conductive via structures 214 have two functions, conductive via structures and conductive pads, there is no need to align conductive pads to conductive via structures, which improves process yield and reduces process cost, in accordance with some embodiments. Furthermore, the conductive via structures 214 are narrower than traditional conductive pads, which improves the layout density of the substrate 100A, in accordance with some embodiments.

As shown in FIG. 1I, an underfill layer UF is formed between the substrate 100A and the chip structure 250, in accordance with some embodiments. The underfill layer UF surrounds the conductive bumps 260, in accordance with some embodiments. The underfill layer UF is made of an insulating material such as a polymer material, in accordance with some embodiments.

As shown in FIG. 1I, conductive bumps 270 are formed under the surface treatment layer 240, in accordance with some embodiments. The conductive bumps 270 are made of a conductive material such as tin (Sn) or alloys thereof, in accordance with some embodiments. In this step, a chip package structure 100 is substantially formed, in accordance with some embodiments.

As shown in FIG. 1I, the chip package structure 100 is bonded to a wiring substrate 280, in accordance with some embodiments. The conductive bumps 270 are connected between the substrate 100A and the wiring substrate 280, in accordance with some embodiments.

The wiring substrate 280 includes a dielectric layer, conductive pads, wiring layers, and conductive vias (not shown), in accordance with some embodiments. The conductive pads are embedded in the dielectric layer, in accordance with some embodiments. The conductive bumps 270 are bonded to the conductive pads of the wiring substrate 280, in accordance with some embodiments.

The wiring layers and the conductive vias of the wiring substrate 280 are formed in the dielectric layer of the wiring substrate 280, in accordance with some embodiments. The conductive vias are electrically connected between different wiring layers and between the wiring layer and the conductive pads, in accordance with some embodiments.

The dielectric layer is made of an insulating material such as a polymer material (e.g., polybenzoxazole or polyimide), nitride (e.g., silicon nitride), oxide (e.g., silicon oxide), silicon oxynitride, or the like, in accordance with some embodiments. The dielectric layer is formed using lamination process (or deposition processes), photolithography processes, and etching processes, in accordance with some embodiments.

The conductive pads are made of a conductive material, such as metal (e.g. copper, aluminum, or tungsten) or alloys thereof, in accordance with some embodiments. The wiring layers are made of a conductive material, such as metal (e.g. copper, aluminum, or tungsten) or alloys thereof, in accordance with some embodiments. The conductive vias are made of a conductive material, such as metal (e.g. copper, aluminum, or tungsten) or alloys thereof, in accordance with some embodiments.

In some embodiments, the conductive pads, the wiring layers, and the conductive vias are made of the same material. In some other embodiments, the conductive pads, the wiring layers, and the conductive vias are made of different materials.

FIGS. 2A-2F are cross-sectional views of various stages of a process for forming a chip package structure, in accordance with some embodiments. As shown in FIG. 2A, the step of FIG. 1D is performed, except that the through holes 152a of FIG. 1D are not formed in the dielectric layer 152 of FIG. 2A, in accordance with some embodiments.

As shown in FIG. 2B, the step of FIG. 1E is performed to form the conductive lines 162 and 172 and the conductive via structures 174, in accordance with some embodiments.

As shown in FIG. 2C, the step of FIG. 1F is performed and portions of the dielectric layer 152 are removed to form through holes 152a, in accordance with some embodiments. The through holes 184 of the dielectric layer 180 are over and connected to the through holes 152a of the dielectric layer 152, in accordance with some embodiments. The through holes 152a and 184 expose portions of the wiring layer 142a, in accordance with some embodiments.

As shown in FIG. 2D, the step of FIG. 1G is performed and the conductive via structures 216 are formed in the through holes 152a and 184, in accordance with some embodiments. The conductive via structures 216 pass through the dielectric layers 152 and 180, in accordance with some embodiments. The conductive via structure 216 is wider than the conductive line 212, in accordance with some embodiments.

The width W216 of the conductive via structure 216 continuously increases from the bottom surface 216b of the conductive via structure 216 to the top surface 216a of the conductive via structure 216, in accordance with some embodiments. The conductive via structure 216 has a trapezoid shape, in accordance with some embodiments. The top surface 216a of the conductive via structure 216 is lower than the top surface 186 of the dielectric layer 180, in accordance with some embodiments.

Since the conductive via structures 216 pass through the dielectric layers 152 and 180, there is no need to align the conductive via structures 214 to the conductive via structures 164 of FIG. 1G, which improves process yield and reduces process cost, in accordance with some embodiments.

As shown in FIG. 2E, the step of FIG. 1H is performed to form the solder resist layer 230 and the surface treatment layer 240, in accordance with some embodiments. In this step, a substrate 200A is substantially formed, in accordance with some embodiments.

As shown in FIG. 2F, the step of FIG. 1I is performed to form the chip structure 250, the conductive bumps 260, the underfill layer UF, and the conductive bumps 270, in accordance with some embodiments. In this step, a chip package structure 200 is substantially formed, in accordance with some embodiments. As shown in FIG. 2F, the step of FIG. 1I is performed to form the wiring substrate 280, in accordance with some embodiments.

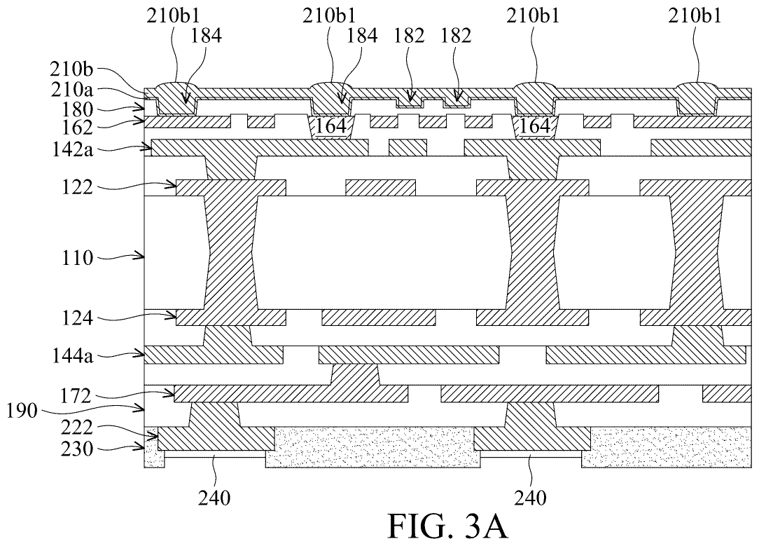

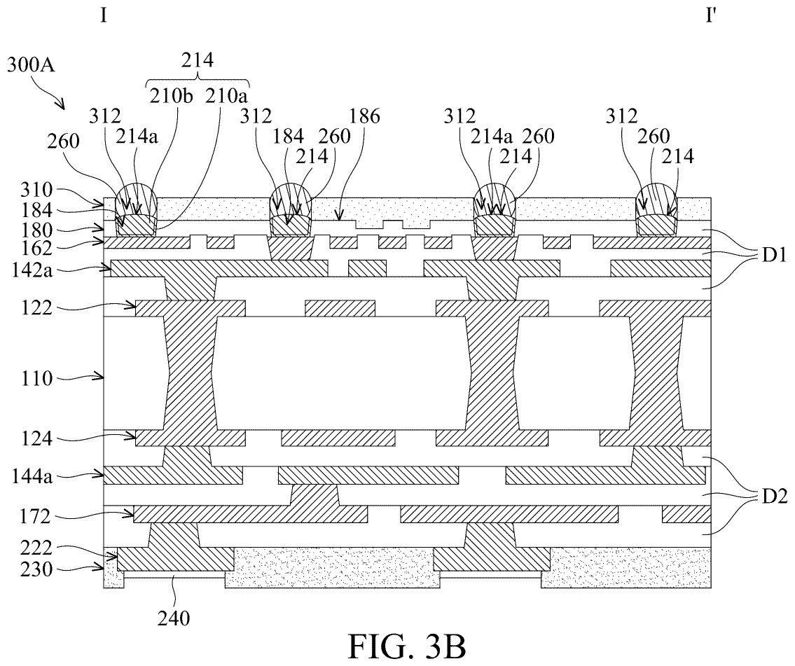

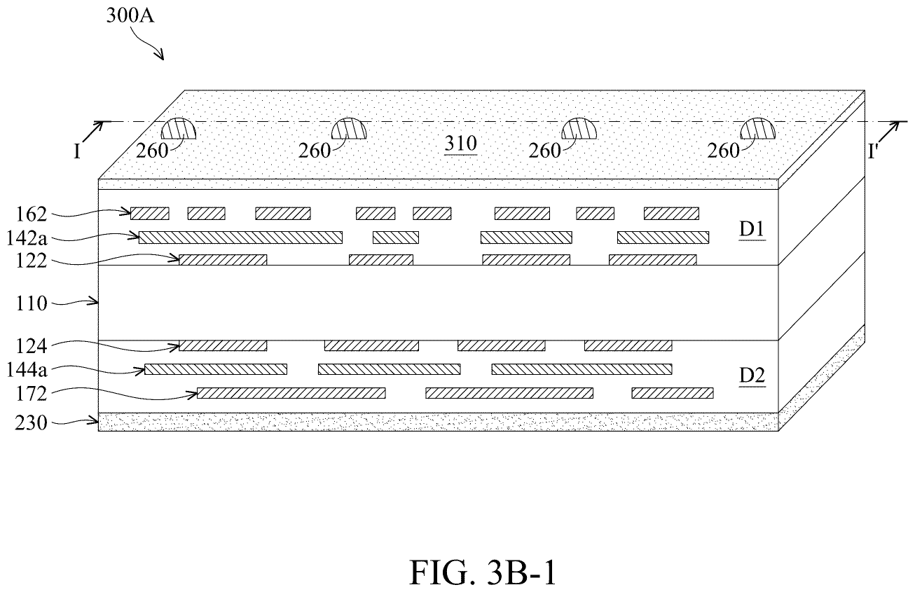

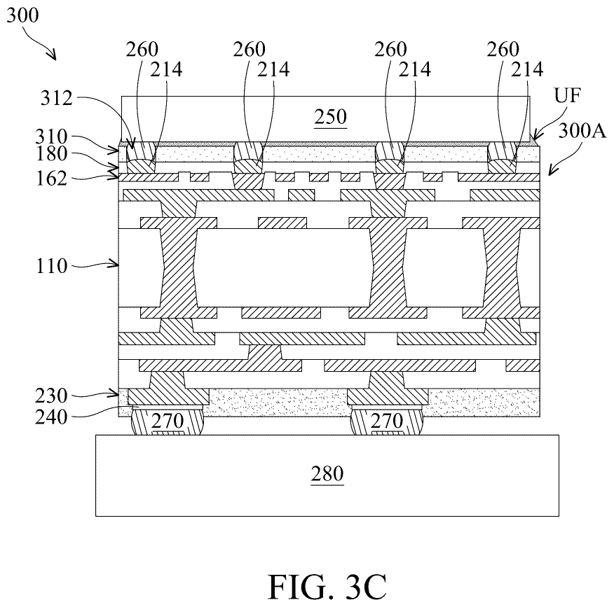

FIGS. 3A-3C are cross-sectional views of various stages of a process for forming a chip package structure, in accordance with some embodiments. As shown in FIG. 3A, after the step of FIG. 1F, a seed layer 210a is formed over the dielectric layer 180, the conductive lines 162, and the conductive via structures 164, in accordance with some embodiments. The seed layer 210a is made of a conductive material, such as metal (e.g. copper, aluminum, or tungsten) or alloys thereof, in accordance with some embodiments.

As shown in FIG. 3A, a conductive layer 210b is formed over the seed layer 210a, in accordance with some embodiments. The forming rate of the conductive layer 210b in a wide recess is greater than that in a narrow recess, in accordance with some embodiments. Therefore, the forming rate of the conductive layer 210b in the through holes 184 is greater than that in the trenches 182, in accordance with some embodiments. The conductive layer 210b has protruding portions 210b1 over the through holes 184, in accordance with some embodiments.

FIG. 3B-1 is a perspective view of the chip package structure of FIG. 3B, in accordance with some embodiments. FIG. 3B is a cross-sectional view illustrating the chip package structure along a sectional line I-I′ in FIG. 3B-1, in accordance with some embodiments.

As shown in FIGS. 3B and 3B-1, upper portions of the seed layer 210a and the conductive layer 210b are removed to expose the top surface 186 of the dielectric layer 180, in accordance with some embodiments. The seed layer 210a and the conductive layer 210b remaining in the same through hole 184 together form a conductive via structure 214, in accordance with some embodiments.

The conductive via structure 214 has a convex surface 214a, in accordance with some embodiments. The convex surface 214a protrudes from the top surface 186 of the dielectric layer 180, in accordance with some embodiments. The convex surface 214a is a convex curved surface, in accordance with some embodiments. The removal process includes an etching process, in accordance with some embodiments.

As shown in FIGS. 3B and 3B-1, a solder resist layer 310 is formed over the dielectric layer 180 and the conductive via structures 214, in accordance with some embodiments. The solder resist layer 310 has openings 312, in accordance with some embodiments. The openings 312 expose the conductive via structures 214, in accordance with some embodiments.

The convex surface 214a of the conductive via structure 214 is in the opening 312 of the solder resist layer 310, in accordance with some embodiments. The solder resist layer 310 is made of an insulating material such as a polymer material, in accordance with some embodiments.

As shown in FIGS. 3B and 3B-1, conductive bumps 260 are formed in the openings 312 of the solder resist layer 310, in accordance with some embodiments. The conductive bumps 260 pass through the solder resist layer 310, in accordance with some embodiments. The conductive bump 260 is in direct contact with the convex surface 214a of the conductive via structure 214, in accordance with some embodiments.

The conductive via structure 214 extends into the conductive bump 260 thereover, in accordance with some embodiments. The conductive bumps 260 are made of a conductive material such as tin (Sn) or alloys thereof, in accordance with some embodiments.

As shown in FIG. 3C, the step of FIG. 1I is performed to form the chip structure 250, the underfill layer UF, and the conductive bumps 270, in accordance with some embodiments. In this step, a chip package structure 300 is substantially formed, in accordance with some embodiments. As shown in FIG. 3C, the step of FIG. 1I is performed to form the wiring substrate 280, in accordance with some embodiments.

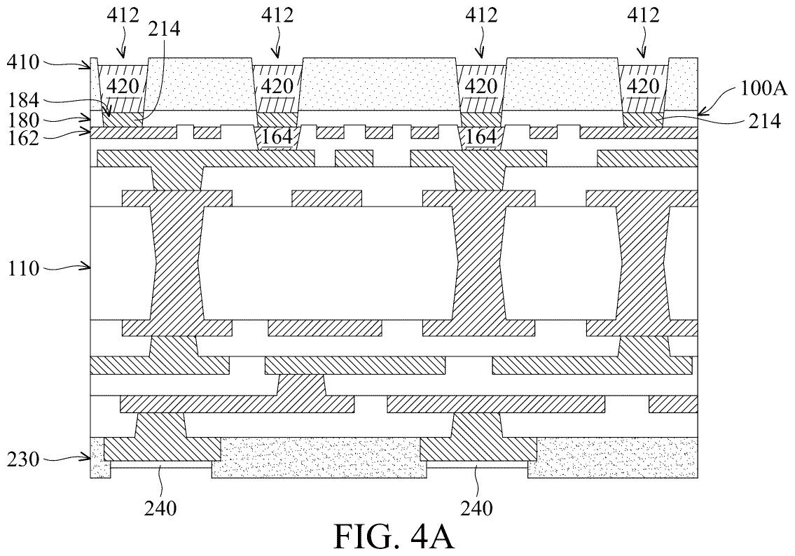

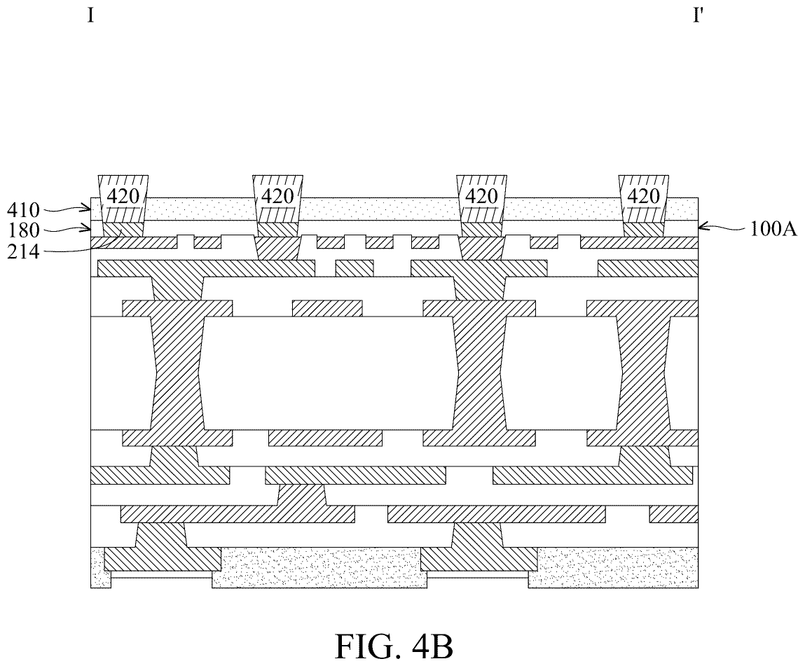

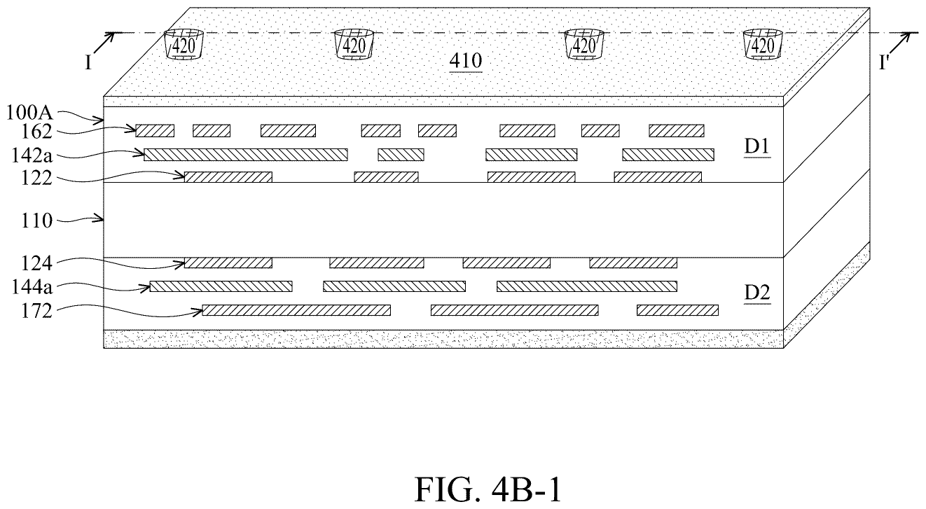

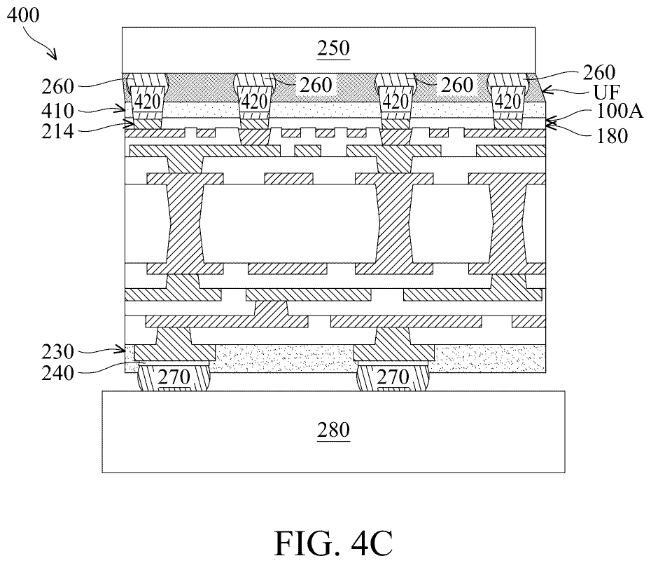

FIGS. 4A-4C are cross-sectional views of various stages of a process for forming a chip package structure, in accordance with some embodiments. As shown in FIG. 4A, after the step of FIG. 1H is performed, a solder resist layer 410 is formed over the dielectric layer 180 and the conductive via structures 214, in accordance with some embodiments.

The solder resist layer 410 has openings 412, in accordance with some embodiments. The openings 412 expose the conductive via structures 214, in accordance with some embodiments. The solder resist layer 410 is made of an insulating material such as a polymer material, in accordance with some embodiments.

As shown in FIG. 4A, conductive bumps 420 are formed in the openings 412 and on the conductive via structures 214, in accordance with some embodiments. The conductive bumps 420 are made of a conductive material, such as metal (e.g. copper, aluminum, or tungsten) or alloys thereof, in accordance with some embodiments.

FIG. 4B-1 is a perspective view of the chip package structure of FIG. 4B, in accordance with some embodiments. As shown in FIGS. 4B and 4B-1, the solder resist layer 410 is thinned, in accordance with some embodiments. The conductive bumps 420 pass through the thinned solder resist layer 410, in accordance with some embodiments.

As shown in FIG. 4C, the step of FIG. 1I is performed to form the chip structure 250, the conductive bumps 260, the underfill layer UF, and the conductive bumps 270, in accordance with some embodiments. In this step, a chip package structure 400 is substantially formed, in accordance with some embodiments. As shown in FIG. 4C, the step of FIG. 1I is performed to form the wiring substrate 280, in accordance with some embodiments.

Processes and materials for forming the chip package structures 200, 300, and 400 may be similar to, or the same as, those for forming the chip package structure 100 described above. Elements designated by the same or similar reference numbers as those in FIGS. 1A to 4C have the same or similar structures and the materials. Therefore, the detailed descriptions thereof will not be repeated herein.

In accordance with some embodiments, semiconductor device structures and methods for forming the same are provided. The methods (for forming the semiconductor device structure) form conductive via structures having two functions, conductive via structures and conductive pads. Therefore, there is no need to align conductive pads to conductive via structures, which improves process yield and reduces process cost. Furthermore, the conductive via structures are narrower than conductive pads, which improves the layout density of a substrate having the conductive via structures.

In accordance with some embodiments, a method for forming a chip package structure is provided. The method includes forming a first dielectric layer over a core substrate. The method includes partially removing the first dielectric layer using a first laser process to form a first through hole passing through the first dielectric layer. The method includes forming a first conductive via structure in the first through hole. A first top surface of the first conductive via structure is lower than a second top surface of the first dielectric layer. The method includes bonding a chip structure to the first conductive via structure through a conductive bump. The conductive bump is in direct contact with the first top surface of the first conductive via structure.

In accordance with some embodiments, a method for forming a chip package structure is provided. The method includes forming a dielectric layer over a core substrate. The method includes partially removing the dielectric layer using a laser process to form a through hole passing through the dielectric layer. The method includes forming a conductive via structure in the through hole. The conductive via structure has a convex surface protruding from a top surface of the dielectric layer. The method includes bonding a chip structure to the conductive via structure through a conductive bump. The conductive bump is in direct contact with the convex surface of the conductive via structure.

In accordance with some embodiments, a chip package structure is provided. The chip package structure includes a core substrate. The chip package structure includes a first dielectric layer over a core substrate. The chip package structure includes a conductive via structure in the first dielectric layer. A width of the conductive via structure continuously increases from a bottom surface of the conductive via structure to a first top surface of the conductive via structure. The chip package structure includes a conductive bump over and in direct contact with the first top surface of the conductive via structure. The chip package structure includes a chip structure over the conductive bump.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a chip package structure, comprising:
forming a first dielectric layer over a core substrate;
partially removing the first dielectric layer using a first laser process to form a first through hole passing through the first dielectric layer;
forming a first conductive via structure in the first through hole, wherein a first top surface of the first conductive via structure is lower than a second top surface of the first dielectric layer; and
bonding a chip structure to the first conductive via structure through a conductive bump, wherein the conductive bump is in direct contact with the first top surface of the first conductive via structure.

2. The method for forming the chip package structure as claimed in claim 1, further comprising:
partially removing the first dielectric layer using a second laser process to form a first trench in the first dielectric layer, wherein the first trench is connected to the first through hole;
forming a first conductive line in the first trench, wherein the first conductive line is connected to the first conductive via structure.

3. The method for forming the chip package structure as claimed in claim 2, wherein a line width of the first conductive line is less than a width of the first conductive via structure.

4. The method for forming the chip package structure as claimed in claim 3, wherein the partially removing of the first dielectric layer further forms a second trench in the first dielectric layer, wherein the first trench is spaced apart from the second trench, and the first trench is wider than the second trench, and
the method further comprises:
forming a second conductive line in the second trench.

5. The method for forming the chip package structure as claimed in claim 1, wherein a width of the first conductive via structure continuously increases from a bottom surface of the first conductive via structure to the first top surface of the first conductive via structure.

6. The method for forming the chip package structure as claimed in claim 1, further comprising:
before forming the first dielectric layer over the core substrate, forming a second dielectric layer over the core substrate;
partially removing the second dielectric layer using a second laser process to form a second through hole passing through the second dielectric layer; and
forming a second conductive via structure in the second through hole, wherein a third top surface of the second conductive via structure is lower than a fourth top surface of the second dielectric layer, the first dielectric layer is formed over the second dielectric layer, and the first conductive via structure is on the third top surface of the second conductive via structure.

7. The method for forming the chip package structure as claimed in claim 6, wherein the first conductive via structure is partially in the second through hole.

8. The method for forming the chip package structure as claimed in claim 6, further comprising:
partially removing the second dielectric layer using a third laser process to form a trench in the second dielectric layer; and
forming a conductive line in the trench, wherein a line width of the conductive line is less than a width of the second conductive via structure.

9. The method for forming the chip package structure as claimed in claim 1, further comprising:
before forming the first dielectric layer over the core substrate, forming a second dielectric layer over the core substrate, wherein the first dielectric layer is formed over the second dielectric layer, and the method further comprises:
partially removing the second dielectric layer using the first laser process to form a second through hole passing through the second dielectric layer, wherein the first conductive via structure is further in the second through hole.

10. The method for forming the chip package structure as claimed in claim 1, further comprising:
after forming the first conductive via structure in the first through hole and before bonding the chip structure to the first conductive via structure, forming a solder resist layer over the first dielectric layer, wherein the solder resist layer has an opening exposing the first conductive via structure, and the conductive bump passes through the solder resist layer.

11. A method for forming a chip package structure, comprising:
forming a dielectric layer over a core substrate;
partially removing the dielectric layer using a laser process to form a through hole passing through the dielectric layer;
forming a conductive via structure in the through hole, wherein the conductive via structure has a convex surface protruding from a top surface of the dielectric layer; and
bonding a chip structure to the conductive via structure through a conductive bump, wherein the conductive bump is in direct contact with the convex surface of the conductive via structure.

12. The method for forming the chip package structure as claimed in claim 11, further comprising:
after forming the conductive via structure in the through hole and before bonding the chip structure to the conductive via structure, forming a solder resist layer over the dielectric layer, wherein the solder resist layer has an opening exposing the conductive via structure, and the conductive bump is in the opening and passes through the solder resist layer.

13. The method for forming the chip package structure as claimed in claim 12, wherein the convex surface of the conductive via structure is in the opening of the solder resist layer.

14. The method for forming the chip package structure as claimed in claim 11, wherein the conductive via structure extends into the conductive bump.

15. The method for forming the chip package structure as claimed in claim 11, wherein the convex surface of the conductive via structure is a convex curved surface.

16. A chip package structure, comprising:
a core substrate;
a first dielectric layer over a core substrate;
a conductive via structure in the first dielectric layer, wherein a width of the conductive via structure continuously increases from a bottom surface of the conductive via structure to a first top surface of the conductive via structure;
a conductive bump over and in direct contact with the first top surface of the conductive via structure; and
a chip structure over the conductive bump.

17. The chip package structure as claimed in claim 16, wherein the first top surface of the conductive via structure is lower than a second top surface of the first dielectric layer.

18. The chip package structure as claimed in claim 16, wherein the conductive bump extends into the first dielectric layer.

19. The chip package structure as claimed in claim 16, further comprising:
a second dielectric layer between the first dielectric layer and the core substrate, wherein the conductive via structure passes through the second dielectric layer.

20. The chip package structure as claimed in claim 16, further comprising:
a solder resist layer over the first dielectric layer, wherein the conductive bump passes through the solder resist layer.
